(19) United States
(12) Patent Application Publication
(10) Pub. No.: US 2025/0182267 A1
(43) Pub. Date: Jun. 5, 2025

(54) SEMICONDUCTOR PACKAGE INSPECTION METHOD AND METHOD OF MANUFACTURING SEMICONDUCTOR DEVICE BY USING THE SAME

(71) Applicants: Samsung Electronics Co., Ltd., Suwon-si (KR); UIF (University Industry Foundation), Yonsei University, Seoul (KR)

(72) Inventors: Jaemin Jeon, Suwon-si (KR); Soonkyu Hwang, Suwon-si (KR); No-Cheol Park, Seoul-si (KR); Tano Kim, Seoul-si (KR); Wanhee Han, Seoul-si (KR); Seongjin Park, Suwon-si (KR); Haegu Lee, Suwon-si (KR)

(73) Assignees: Samsung Electronics Co., Ltd., Suwon-si (KR); UIF (University Industry Foundation), Yonsei University, Seoul (KR)

(21) Appl. No.: 18/816,791

(22) Filed: Aug. 27, 2024

(30) Foreign Application Priority Data
Nov. 30, 2023 (KR) 10-2023-0171831

(51) Int. Cl. G06T 7/00; G01B 11/30; G01N 21/88; G01N 21/95; G06T 7/55; G06T 15/50; H04N 23/56; H04N 23/74

(52) U.S. Cl. CPC G06T 7/001; G01B 11/303; G06T 7/55; G06T 15/506; H04N 23/56; H04N 23/74; G01N 2021/8887; G01N 21/9501; G06T 2200/04; G06T 2207/20056; G06T 2207/30148

(57) ABSTRACT

An inspection method is provided.

The inspection method includes obtaining a plurality of vision images in a surface of a semiconductor device at a latitude and a longitude where a plurality of illuminations are designated, obtaining a bidirectional reflectance distribution function (BRDF) on the surface of the semiconductor device by using the obtained plurality of vision images, rendering a vision image of the semiconductor device at a latitude and a longitude where the plurality of illuminations are not designated, based on the obtained BRDF, performing a two-dimensional (2D) Fourier transform on a synthesis image of the rendered image and the obtained plurality of vision images to calculate a power spectrum density, selecting an integral section of the power spectrum density, and performing an integral on the power spectrum density in the integral section to quantify roughness.

### CROSS-REFERENCE TO RELATED APPLICATION

This application is based on and claims priority under 35 U.S.C. § 119 to Korean Patent Application No. 10-2023-0171831, filed on Nov. 30, 2023, in the Korean Intellectual Property Office, the disclosure of which is incorporated by reference herein in its entirety.

### BACKGROUND

The inventive concept relates to a semiconductor inspection method and a method of manufacturing a semiconductor device by using the same.

In a process of inspecting a semiconductor package, the positions, directions, warping, scratches, omission, and brokenness of various markings representing information about the product name and the manufacturer of the semiconductor device are inspected. As semiconductor packages are progressively miniaturized, much time and cost are consumed by a visual inspection of inspection items, and loss cost occurs due to defective products caused by inaccurate inspection. Therefore, high-performance vision inspection technology has been developed and applied to the field of semiconductor inspection recently.

### SUMMARY

An aspect of the inventive concept provides an inspection method in which reliability is enhanced.

An aspect of the inventive concept provides a method of manufacturing a semiconductor device by using an inspection method, in which reliability is enhanced.

An aspect of the inventive concept provides an inspection method in which reliability is enhanced.

An aspect of the inventive concept provides a method of manufacturing a semiconductor device by using an inspection method, in which reliability is enhanced.

An inspection method according to an embodiment includes providing a semiconductor package including a surface. The surface includes a plurality of segments. The inspection method further includes obtaining a plurality of vision images by using light from a plurality of illuminations. The plurality of illuminations are disposed at first positions corresponding to a first set of latitudes and longitudes. The inspection method further includes obtaining a bidirectional reflectance distribution function (BRDF) on the surface by using the plurality of vision images, and rendering the plurality of vision images by using the BRDF to obtain a rendered image including an image information obtained by using virtual light. The virtual light is from a plurality of virtual illuminations disposed at second positions corresponding to a second set of latitudes and longitudes. The first set of latitudes and longitudes is different from the second set of latitudes and longitudes. The inspection method further includes performing a two-dimensional (2D) Fourier transform on a first synthesis image of the rendered image and at least portion of the plurality of vision images to obtain a power spectrum density (PSD) on the surface, selecting an integral section of the PSD, and performing an integral on the PSD in the integral section to quantify roughness of the surface.

An inspection method according to an embodiment includes providing an inspection apparatus. The inspection apparatus includes a semispherical housing, and a light receiver disposed at an uppermost vertex of the semispherical housing. The light receiver is single one light receiver. The inspection apparatus further includes a plurality of illuminations disposed on the semispherical housing. The plurality of illuminations is spaced apart from each other, disposed at first positions corresponding to a first set of latitudes and longitudes, disposed repeatedly by a latitudinal interval in each longitudes, and disposed repeatedly by a longitudinal interval in each latitudes. The inspection method further includes providing a semiconductor package including a surface, inputting power to one or more of the plurality of illuminations to irradiate light onto the surface of the semiconductor package, obtaining a plurality of vision images by detecting reflected light from the surface of the semiconductor package by using the light receiver, obtaining a BRDF on the surface of the semiconductor package by using the plurality of vision images, and rendering the plurality of vision images by using the BRDF to obtain a rendered image including an image information obtained by using virtual light. The virtual light is from a plurality of virtual illuminations disposed at second positions corresponding to a second set of latitudes and longitudes. The first set of latitudes and longitudes is different from the second set of latitudes and longitudes. The inspection method further includes determining a measurement target of roughness of the surface, selecting at least portion of the plurality of vision images based on the latitude of each of the plurality of illuminations and the measurement target, obtaining a second synthesis image of the rendered image and the at least portion of the plurality of vision images, performing a 2D Fourier transform on the second synthesis image to calculate a PSD, selecting an integral section of the PSD, and performing an integral on the PSD in the integral section to quantify the roughness.

A semiconductor manufacturing method according to an embodiment includes preparing a wafer, performing a semiconductor manufacturing process on the wafer to obtain a semiconductor package, and inspecting the semiconductor package. The inspecting of the semiconductor package includes obtaining a plurality of vision images of a surface of the semiconductor package by using light from a plurality of illuminations with respect to an illumination designation region, obtaining a BRDF on the surface of the semiconductor package by using the plurality of vision images, obtain a rendered image including an image information obtained by using virtual light by using the BRDF with respect to an illumination non-designation region, determining a measurement target of roughness of the surface of the semiconductor package, selecting at least portion of the plurality of vision images based on a position of each of the plurality of illuminations and the measurement target, performing a 2D Fourier transform on a first synthesis image of the rendered image and the at least portion of the plurality of vision images to obtain a power spectrum density (PSD) on the surface, selecting an integral section of the PSD, and performing an integral on the PSD in the integral section to quantify the roughness.

### BRIEF DESCRIPTION OF THE DRAWINGS

Embodiments will be more clearly understood from the following detailed description taken in conjunction with the accompanying drawings in which:

FIG. 1 is a flowchart of a semiconductor package inspection method according to an embodiment;

FIG. 2A is a perspective view illustrating a semiconductor package inspection apparatus which is used in performing a semiconductor package inspection method, according to an embodiment;

FIG. 2B is a plan view illustrating longitudes of a plurality of illuminations according to an embodiment;

FIG. 2C is a plan view illustrating latitudes and longitudes of a plurality of illuminations according to an embodiment;

FIG. 3 is a flowchart of an operation of obtaining a vision image according to an embodiment;

FIG. 4 is a flowchart of an operation of obtaining a bidirectional reflectance distribution function according to an embodiment;

FIG. 5 is a flowchart of an operation of rendering a vision image of a semiconductor package, according to an embodiment;

FIG. 6 is a flowchart of an operation of selecting an integral section of a power spectrum density function, according to an embodiment;

FIG. 7A is a graph showing a correlation of a power spectrum density with respect to a space frequency, according to an embodiment;

FIG. 7B is a graph showing a correlation of a slope absolute value of a power energy spectrum density with respect to a space frequency, according to an embodiment;

FIG. 7C is a graph showing an integral section according to an embodiment;

FIG. 8 is a flowchart of an operation of selecting an integral section of a power spectrum density function, according to another embodiment;

FIG. 9A is a flowchart of an operation of performing an integral on a power spectrum density, according to an embodiment;

FIG. 9B is a flowchart of an operation of performing an integral on a power spectrum density, according to another embodiment;

FIG. 10 is a graph showing a correlation of a power spectrum density integral value with respect to an index, according to another embodiment;

FIG. 11A is a graph showing an index according to an embodiment;

FIG. 11B is a graph showing an index according to another embodiment;

FIG. 11C is a graph showing an index according to another embodiment;

FIG. 12 is a flowchart of a method of manufacturing a semiconductor device by using a semiconductor package inspection method, according to an embodiment; and

FIG. 13 is a schematic block diagram of a semiconductor package inspection apparatus according to an embodiment.

### DETAILED DESCRIPTION OF THE EMBODIMENTS

Embodiments may be variously modified and may have various forms, and thus, some embodiments may be illustrated in the drawings and will be described in detail. However, these are not intended to limit embodiments to a specific form. Also, embodiments described below may be merely examples, and various modifications may be made from the embodiments.

All embodiments or the terms used herein are for explaining the inventive concept in detail, and unless defined by the claims, the scope of the inventive concept is not limited by embodiments or the terms.

Herein, unless specially described below, a vertical direction may be defined as a Z direction, and each of a first direction and a second direction may be defined as a vertical direction perpendicular to the Z direction. The first direction may be referred to as X, and the second direction may be referred to as Y. A vertical level may be referred to as a height level in a vertical direction Z. A horizontal width may denote a length in a horizontal direction X and/or Y, and a vertical length may denote a length in the vertical direction Z. It should be noted that items described in the singular herein, may be provided in plural, as can be understood in the various figures and/or the context in which they are described.

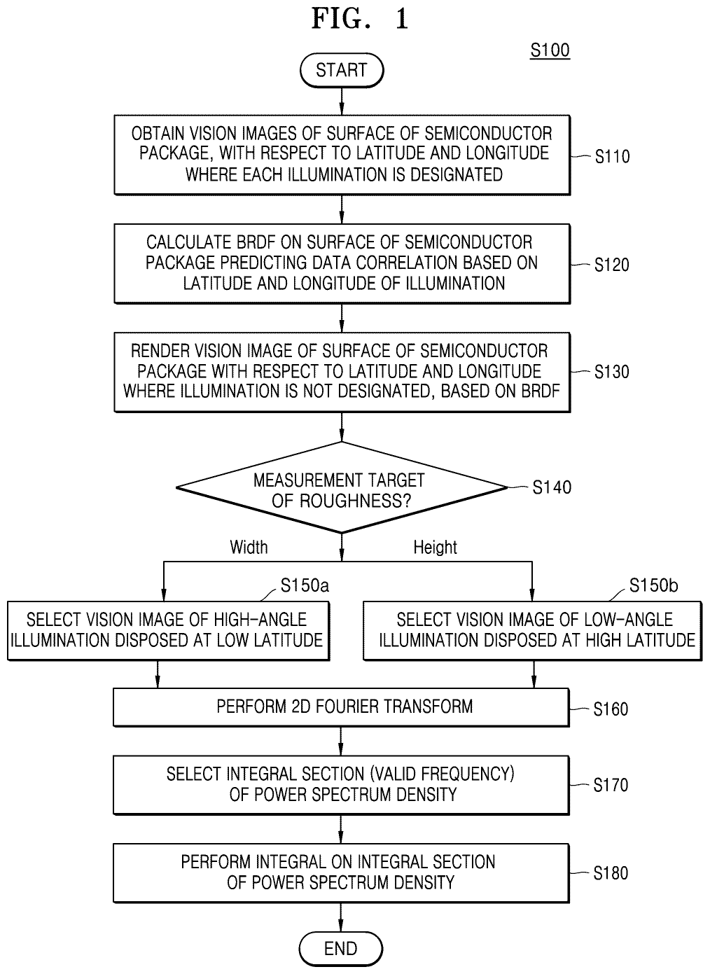

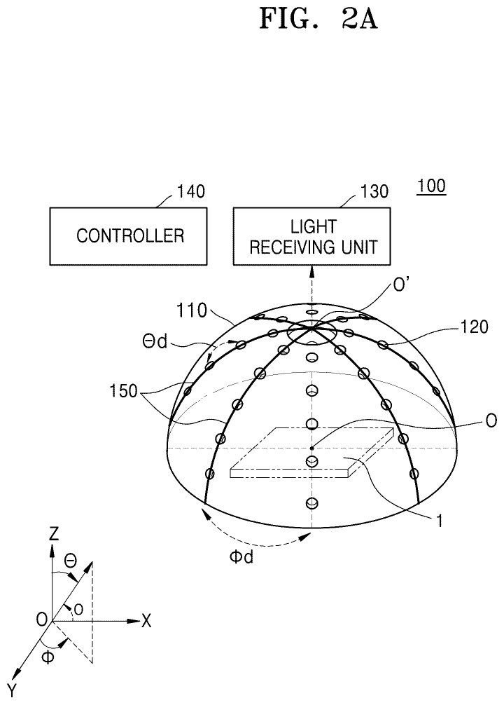

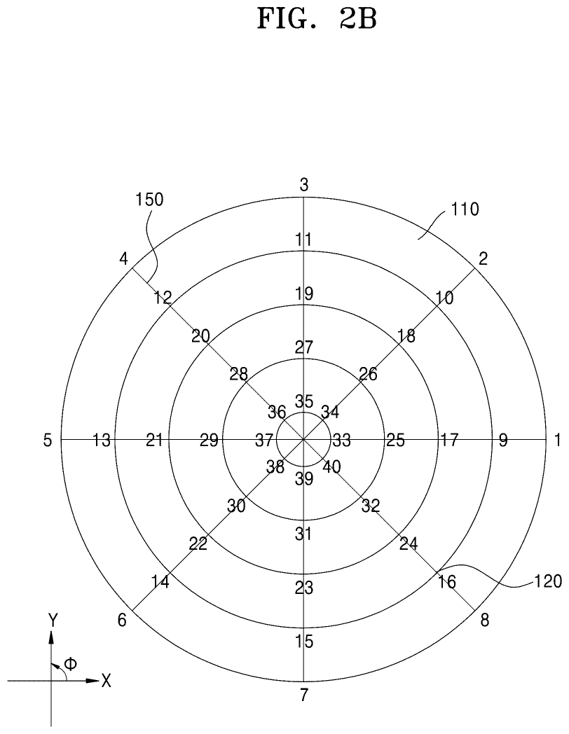

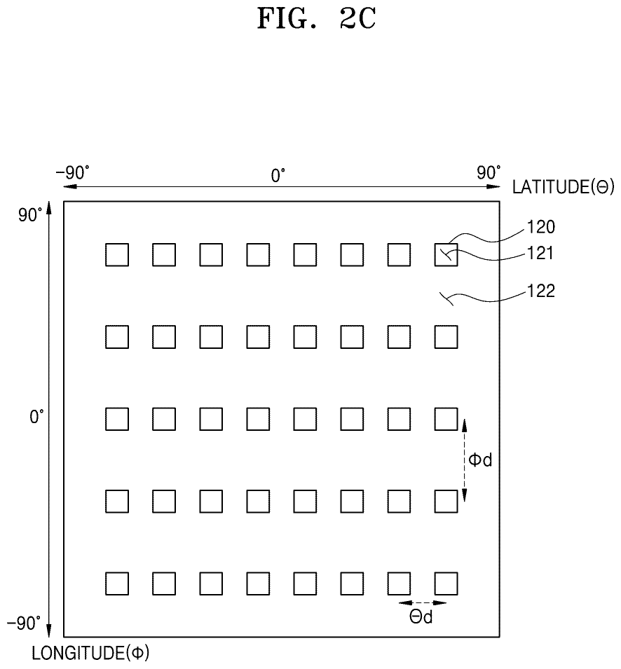

FIG. 1 is a flowchart of a semiconductor package inspection method S100 according to an embodiment. FIG. 2A is a perspective view illustrating a semiconductor package inspection apparatus 100 which is used in performing a semiconductor package inspection method, according to an embodiment. FIG. 2B is a plan view illustrating longitudes of a plurality of illuminations according to an embodiment. FIG. 2C is a plan view illustrating latitudes and longitudes of a plurality of illuminations according to an embodiment. The method S100 may also be used to inspect a semiconductor wafer.

Referring to FIG. 1 in conjunction with FIGS. 2A to 2C, the semiconductor package inspection method S100 of FIG. 1 may be performed by using the semiconductor package inspection apparatus 100 of FIG. 2A. The semiconductor package inspection apparatus 100 may include a semispherical housing 110, a plurality of illuminations 120 disposed on an upper surface of the housing 110, a light receiving unit 130 (also referred to as “light receiver”) disposed at an uppermost vertex O′ of the housing 110 in a spherical coordinate system, and a controller 140 which controls the plurality of illuminations 120 and the light receiving unit 130. A sample to be inspected may be disposed in the semispherical housing 110. In an embodiment, the sample may be a semiconductor package 1. In another embodiment, the sample may be a semiconductor wafer.

The plurality of illuminations 120 may be arranged (i.e., disposed) along circumferences 150 of the housing 110. The circumferences 150 may extend across the uppermost vertex O′ and may be set for being spaced apart to each other by a longitudinal interval Φd at a certain latitude in the spherical coordinate system. Also, the plurality of illuminations 120 may be disposed repeatedly by a latitudinal interval θd in each longitudes. For example, a plurality of illuminations 120, which are disposed along each of the circumferences 150, may be disposed for being spaced apart to each other by a latitudinal interval θd in the spherical coordinate system. In an embodiment, in a spherical coordinate system, the plurality of illuminations 120 may be arranged apart from one another by a latitudinal interval θd of about 15 degrees except 0 degree, from a latitude θ of about −75 degrees to a latitude θ of about 75 degrees. For example, the plurality of illuminations 120, which are disposed along each of the circumferences 150, may be disposed at latitudes θ about −15 degrees, −30 degrees, −45 degrees, −60 degrees, −75 degrees, 15 degrees, 30 degrees, 45 degrees, 60 degrees and 75 degrees. For example, the plurality of the illuminations 120 may be located between latitude of about −75 degrees to about −15 degrees or about 75 degrees to about 15 degrees in each longitude.

The plurality of illuminations 120 may be disposed repeatedly by a longitudinal interval Φd in each latitudes. In an embodiment, in a spherical coordinate system, the plurality of illuminations 120 may be arranged apart from one another by a longitudinal interval Φd of about 45 degrees, at a longitude Φ of about 0 degree to a longitude Φ of about 315 degrees. For example, the plurality of illuminations 120 at a certain latitude may be disposed at longitudes Φ about 0 degree, 45 degrees, 90 degrees, 135 degrees, 180 degrees, 225 degrees, 270 degrees, and 315 degrees. For example, the plurality of illuminations 120 in each latitudes may be located between longitude of about 0 degree to about 315 degrees in each latitudes. However, the angles are only for exemplary embodiments of the invention, and not limited thereto.

Values denoted by longitude Φ, longitudinal interval Φd latitude θ and latitudinal interval θd are described in FIG. 2A, as herein used in the spherical coordinate system. A plane being across the origin O of longitude and latitude of the spherical coordinate system may be extending along the horizontal directions X and Y and contact the bottom of the semispherical housing 110.

In an embodiment, the semiconductor package inspection apparatus 100 may not include a plurality of light receiving units, but a single one of the light receiving unit 130 may be disposed at the uppermost vertex O′ of the semispherical housing 110 in the semiconductor package inspection apparatus 100. Accordingly, the configuration and operation of the inspection apparatus 100 may be simplified, and the inspection method may be more efficiently performed. The uppermost vertex O′ of the semispherical housing 110 may denote a position at which the latitude θ is about 0 degree and the longitude Φ is about 0 degree. In an embodiment, the light receiver (i.e., light receiving unit) 130 may be a camera.

The semiconductor package inspection method S100 may include operation S110 of obtaining a vision image of a surface of the semiconductor package 1, with respect to a latitude θ and a longitude Φ where each of the illuminations 120 is designated. For example, the plurality of illuminations 120 may be disposed at first positions corresponding to a first set of latitudes and longitudes. Each of the plurality of illuminations 120 may irradiate light onto the surface of the semiconductor package 1 which is the sample. The light irradiated onto the semiconductor package 1 may be reflected and may be transferred as reflected light to the light receiving unit 130. The plurality of illuminations 120 may be configured so that the intensity and wavelength of light are individually adjusted by the controller 140 and a band of a wavelength may be a visible light band. For example, the controller 140 may control the plurality of illuminations 120 individually, thereby configuring each of the illuminations 120 to illuminate light of its own intensity and wavelength, and to be turned on or off. Therefore, the illuminating positions as well as the wavelength and intensity of light may be independently adjusted. The light from each of illuminations 120 may be selected to have a wavelength of visible light.

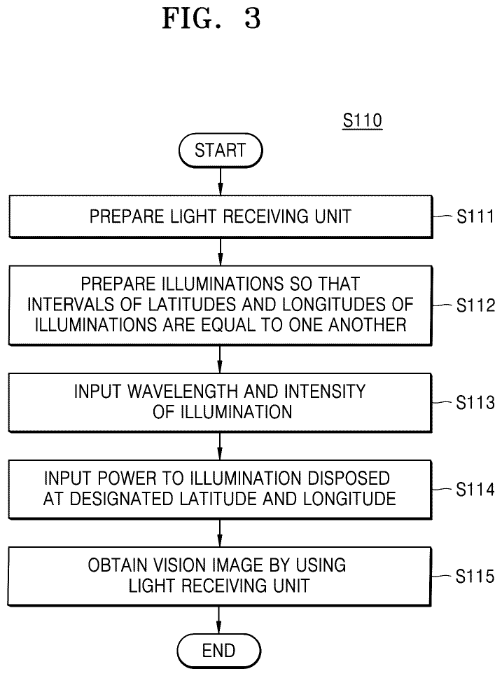

The semiconductor package inspection method S100 may include operation S110 of obtaining a plurality of vision images of the surface of the semiconductor package 1, with respect to a latitude and a longitude where each of the plurality of illuminations 120 is designated. A detailed process of operation S110 of obtaining the plurality of vision images is described with reference to FIG. 3.

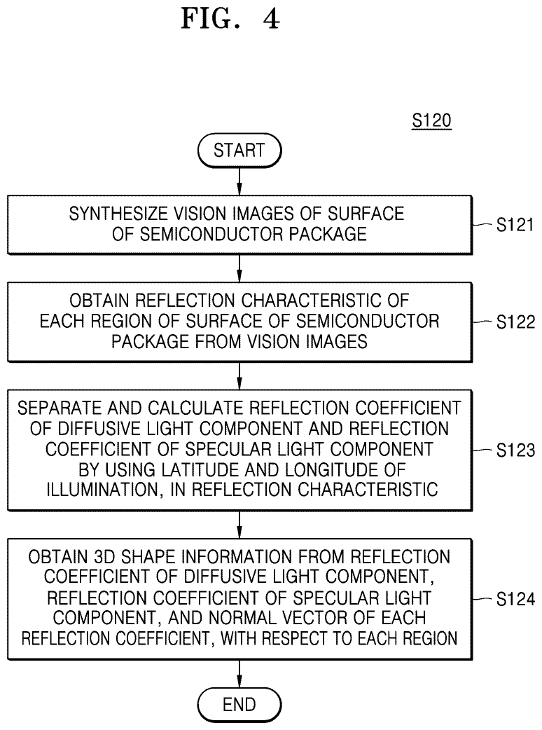

The semiconductor package inspection method S100 may include operation S120 of calculating a bidirectional reflectance distribution function (BRDF) on the surface of the semiconductor package 1 by using the vision images which are obtained in operation S110 of obtaining the vision images. A detailed process of operation S120 of calculating the BRDF is described with reference to FIG. 4.

The semiconductor package inspection method S100 may include operation S130 of rendering a vision image of the surface of the semiconductor package 1 with respect to a latitude θ and a longitude Φ where the illumination 120 is not designated, based on the BRDF which is obtained in operation S120 of calculating the BRDF.

Referring to FIG. 2B, the plurality of illuminations 120 may be arranged for each positions of a plurality of latitudes θ and a plurality of longitudes (along the circumferences 150 of the housing 110. In an embodiment, the illuminations 120 may be disposed for each position of No. 1 to No. 40 positions, and thus, a total of 40 illuminations 120 may be provided. For example, position of No. 1 to No. 8, No. 9 to No. 16, No. 17 to No. 24, No. 25 to No. 32, and No. 33 to No. 40 may be disposed at the same latitude θ. For example, positions of No. 1, No. 9, No. 17, No. 25, and No. 33 may be disposed at the same longitude Φ. Although not shown in the drawing, all circumferences 150 mat meet at the uppermost vertex O′, and at which the light receiving unit 130 is disposed. A longitudinal interval Φd between illuminations 120 disposed positions of No. 1 and No. 2 may be about 45 degrees.

Referring to FIG. 2C, the plurality of illuminations 120 disposed in the housing 110 with respect to a latitude θ and a longitude Φ of about −90 degrees to about 90 degrees are schematically illustrated. In FIG. 2C, at a certain latitude θ between about −90 degrees to about 90 degrees, five illuminations 120 may be arranged. The five illuminations 120 may be spaced apart from each other by a certain longitudinal interval Φd. At a certain longitude Φ between about −90 degrees to about 90 degrees, eight illuminations 120 may be arranged. The eight illuminations 120 may be spaced apart from each other by a certain latitudinal interval θd.

A region of a latitude θ and a longitude Φ, where the illumination 120 is designated, may be defined as an illumination designation region 121, as herein used. A region of latitudes θ and longitudes Φ, where the illumination 120 is not designated, may be defined as an illumination non-designation region 122, as herein used. Power may not always be input to the illuminations 120. Depending on the case, power may not be input to some of the illuminations 120 so as to be turned off. However, the regions for the turned-off illuminations 120 may not be defined as the illumination non-designation region 122 and may be still defined as the illumination designation region 121.

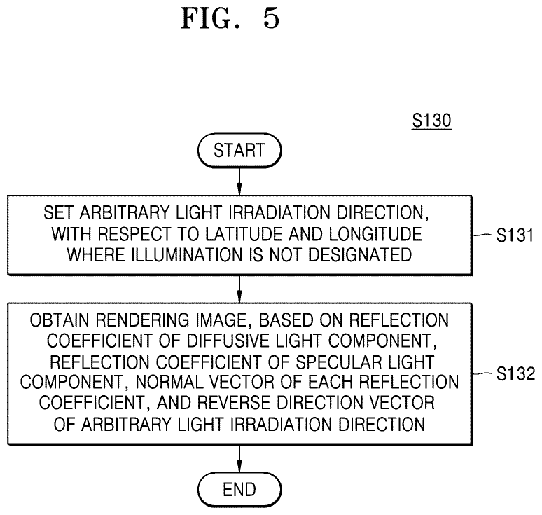

In an embodiment, in the semiconductor package inspection method S100 may include operation S130 of rendering the vision image of the surface of the semiconductor package 1. The rendering may be performed by conducting a simulation in a condition of virtual illuminations being disposed at the illumination non-designation region 122. A detailed process of operation S130 of rendering the vision image of the surface of the semiconductor package 1 is described with reference to FIG. 5.

The semiconductor package inspection method S100 may include operation S140 of determining a measurement target of roughness of the surface of the semiconductor package 1, based on a synthesis image of the obtained plurality of vision images and the rendered image. The semiconductor package inspection method S100 may include an operation of selecting a portion of vision images corresponding to the illuminations 120 for selected latitudes θ, based on the determined measurement target.

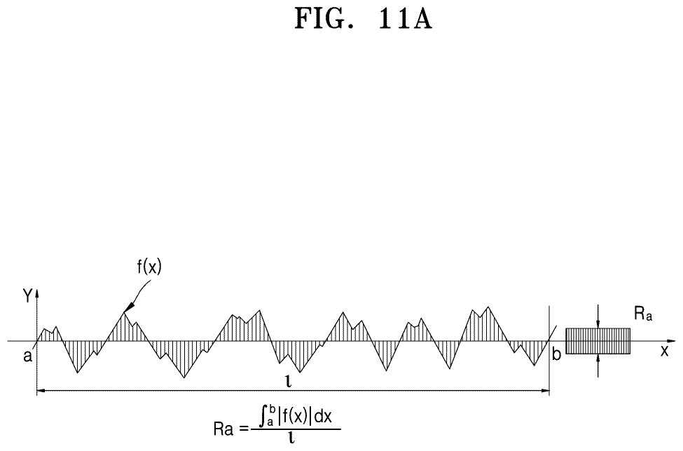

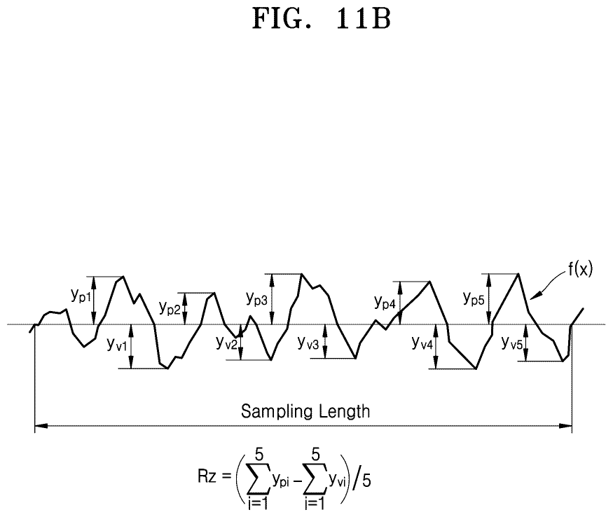

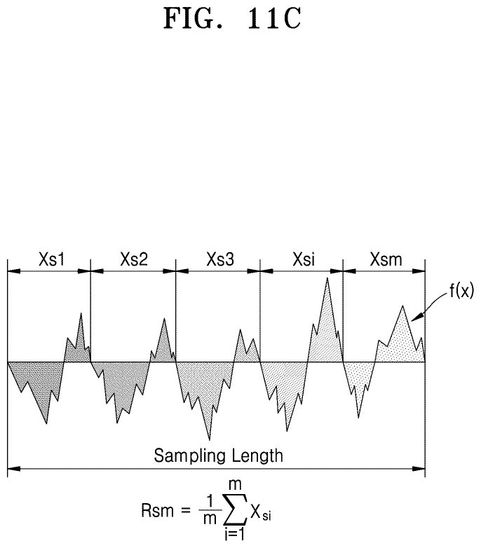

In an embodiment, when the measurement target is a width, the at least portion of the plurality of vision images is obtained by using light from high-angle illuminations disposed at a first latitudes. Each of the first latitudes may have a value between about −15 degrees and about 15 degrees. For example, when the determined measurement target of roughness is a width, the semiconductor package inspection method S100 may include an operation S150a of selecting vision images obtained by high-angle illuminations disposed at low latitudes θ. As herein used in the spherical coordinate system, a latitude θ may be a value of turning which increases while rotating clockwise from a polar axis (i.e., an axis in the vertical direction Z), and an angle (°) may denote a value of turning which increases progressively toward the polar axis from the surface of the ground (i.e., a plane extending along the horizontal directions X and Y) contacting the bottom of the semispherical housing 110, as described in FIG. 2A. The low latitude θ may be a latitude in a range between about −15 degrees to about 15 degrees. For example, only vision images obtained by the illuminations 120 disposed near the light receiving unit 130 may be selected and used to perform Fourier transform described in a later step. Therefore, when roughness of the surface of the semiconductor package 1 is obtained, a horizontal-direction width of the roughness may be more clearly differentiated (i.e., an information having high-sensitivity and/or high resolution may be obtained) than a vertical-direction height of the roughness. An index of a width of roughness may be defined as a width average Rsm of a profile factor, as described in detail with reference to FIG. 11C.

In an embodiment, when the measurement target is a height, the at least portion of the plurality of vision images is obtained by using light from low-angle illuminations disposed at a second latitudes. Each of the second latitudes may have a value between about −90 degrees and −75 degrees or between about 75 degrees to about 90 degrees. For example, when a determined measurement target of roughness is a height, the semiconductor package inspection method S100 may include operation S150b of selecting vision images obtained by low-angle illuminations disposed at high latitudes θ. Here, the definitions of a latitude θ and an angle (°) may be the same as the above descriptions. The high latitude θ may be a latitude in a range between about −90 degrees to about −75 degrees or in a range between about 75 degrees to about 90 degrees. For example, only vision images, which are obtained by illuminations 120 disposed apart from the light receiving unit 130 and disposed near the surface of the ground contacting the housing 110, may be selected and used. Therefore, when roughness of the surface of the semiconductor package 1 is obtained, the vertical-direction height of the roughness may be more clearly differentiated than the horizontal-direction width of the roughness. An index of the height of the roughness may be defined as a center line average value Ra and a ten-point average roughness Rz, as described in detail with reference to FIGS. 11A and 11B.

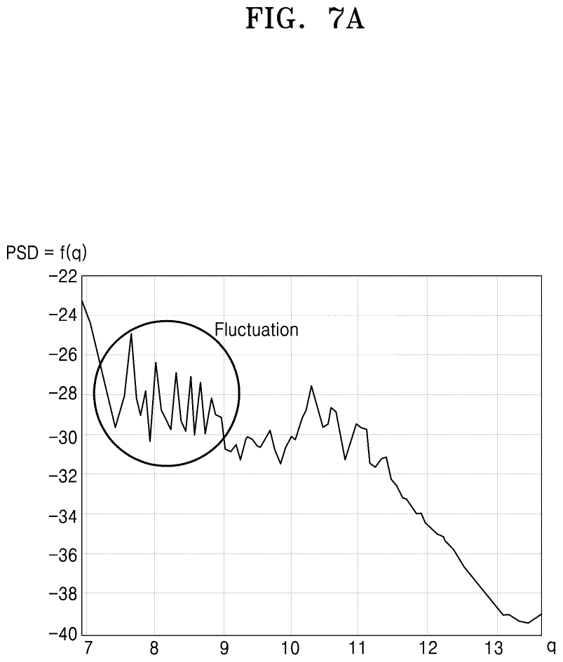

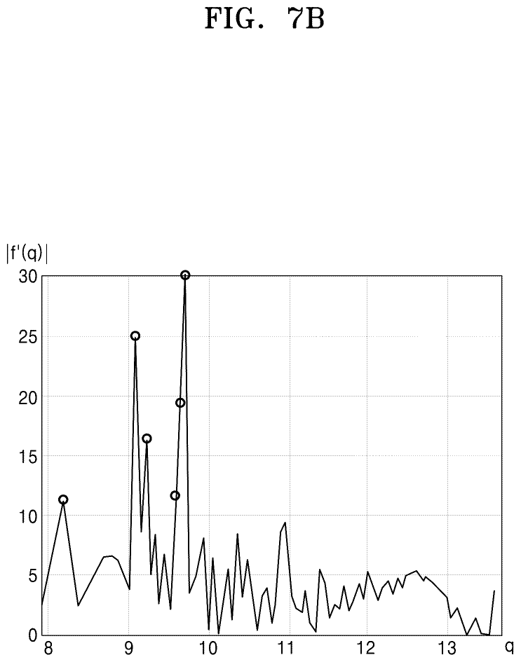

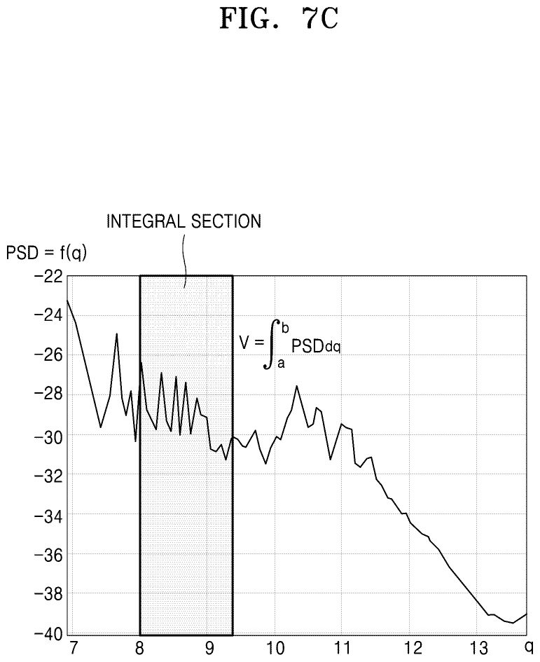

The semiconductor package inspection method S100 may include operation S160 of performing a two-dimensional (2D) Fourier transform on each of selected rendering vision images to calculate a power spectrum density (PSD). In more detail, as in FIG. 7A, the PSD may be changed to a function of a space frequency q. In the function of a space frequency on the PSD according to an embodiment, the x axis may represent, for example, a value of a log function of the space frequency q value.

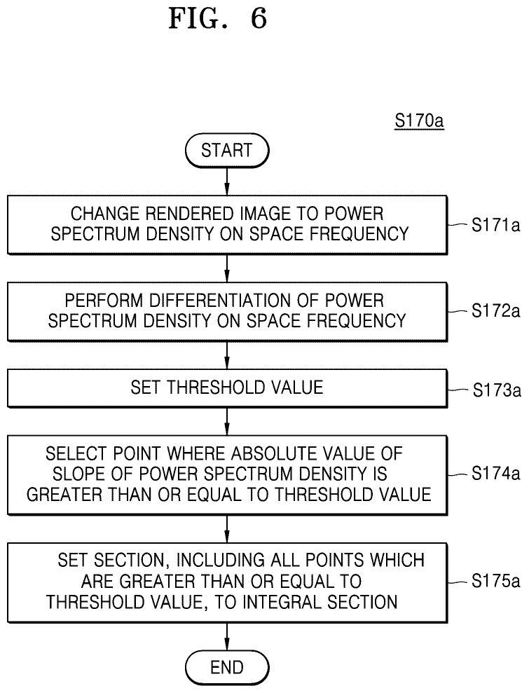

The semiconductor package inspection method S100 may include operation S170 of selecting an integral section in a function graph corresponding to the space frequency q and the PSD obtained by performing a 2D Fourier transform. Here, the integral section may denote a range of valid frequency and may be defined as a range of fluctuation space frequency where a variation of an amplitude is large, in a graph of the function. Operation S170 of selecting the integral section is described in detail with reference to FIGS. 6 to 8.

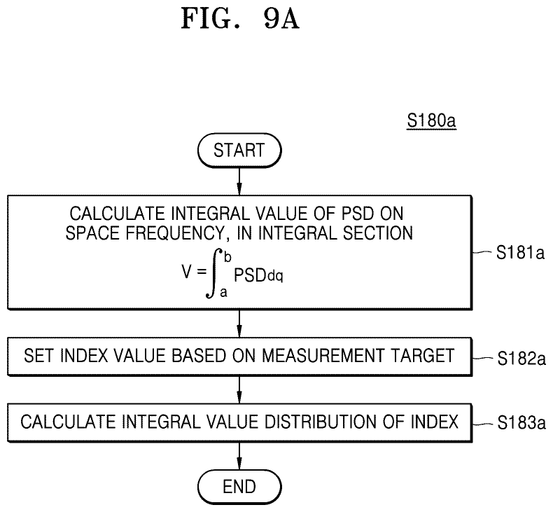

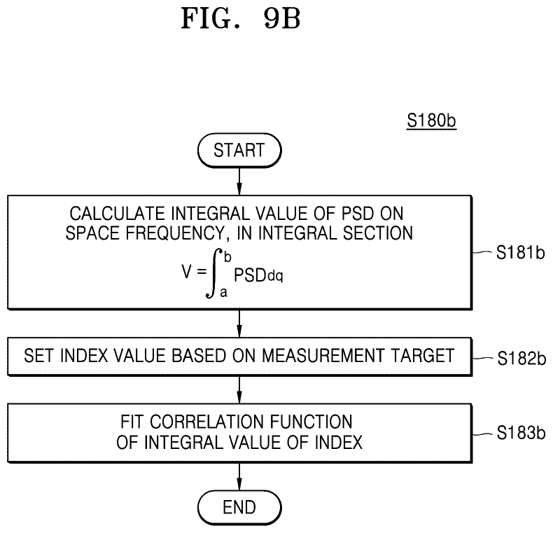

The semiconductor package inspection method S100 may include operation S180 of performing an integral on the integral section, which is selected in operation S170 of selecting the integral section, to quantify roughness. Operation S180 of performing an integral to quantify roughness may include an operation of performing an integral on a corresponding integral section and an operation of selecting an index value based on a roughness measurement target. Operation S180 may further include an operation of calculating an integral value distribution of the index and/or an operation of fitting. Operation S180 of performing an integral to quantify roughness is described in detail with reference to FIGS. 9A to 11C.

FIG. 3 is a flowchart of an operation of obtaining a vision image according to an embodiment. FIG. 3 may be described in conjunction with FIGS. 2A to 2C.

Referring to FIG. 3, operation S110 of obtaining the vision image may include operation S111 of preparing the light receiving unit 130 and operation S112 of preparing a plurality of illuminations 120 so that intervals are equal to one another in latitude θ and longitude Φ of each illumination 120. The light receiving unit 130 may be prepared to be disposed at the uppermost vertex O′ of the semispherical housing 110. For example, the plurality of illuminations 120 may be disposed on the semispherical housing 110. The plurality of illuminations 120 may be spaced apart from each other, and disposed at first positions corresponding to a first set of latitudes and longitudes. The plurality of illuminations 120 may be disposed repeatedly by a latitudinal interval in each longitudes, and disposed repeatedly by a longitudinal interval in each latitudes.

Operation S110 of obtaining the vision image may include operation S113 of inputting a wavelength and intensity of an illumination by using the controller 140. The wavelength and the intensity of illumination may be individually input to each of the illuminations 120, and thus, each of the plurality of illuminations 120 may be individually controlled. An input wavelength band may be a visible light band, but is not limited thereto and may correspond to an infrared range or an ultraviolet range. For example, the controller 140 may input an information of wavelength and intensity to the plurality of illuminations 120. The plurality of illuminations 120 may be disposed repeatedly by a latitudinal interval θd in each longitudes, and the plurality of illuminations 120 may be disposed repeatedly by a longitudinal interval Φd in each latitudes.

Operation S110 of obtaining the vision image may include operation S114 of inputting power to an illumination 120 disposed at a latitude θ and a longitude Φ which are designated. Referring to FIG. 2C, only a portion of the illuminations 120, which is selected to obtain a vision image among a plurality of illuminations 120 and disposed at an illumination designation region 121, may be turned on. Power may be input to the designated illumination (or illuminations) 120. For example, power is input to one or more of the plurality of illuminations 120 to irradiate light onto the surface of the semiconductor package 1. For example, all illuminations 120 disposed at the illumination designation region 121 may not be turned on, but a portion selected among the plurality of illuminations 120 may be turned on. The portion of the illumination 120, to which the power is supplied, may irradiate light onto the surface of the semiconductor package 1 disposed in the housing 110.

Operation S110 of obtaining the vision image may include operation S115 of obtaining a vision image by using the light receiving unit 130. The plurality of vision images of a surface of the semiconductor package 1 may be obtained by using light from a plurality of illuminations 120 with respect to an illumination designation region. The light receiving unit 130 may detect scattered light, which is generated as the light irradiated onto the surface of the semiconductor package 1. The scattered light is reflected from the surface of the semiconductor package 1. The vision image obtained by the light receiving unit 130 is not limited to one and may be provided in plurality. Because the latitude θ and longitude Φ of each of the illuminations 120 is different from others, only pieces of the scattered lights, which are the reflection of the light irradiated by a specific illumination 120, may be detected respectively. Accordingly, the plurality of vision images may be obtained respectively from each of the pieces of scattered light.

FIG. 4 is a flowchart of an operation of obtaining a BRDF according to an embodiment. FIG. 4 may be described in conjunction with FIGS. 2A to 2C.

Referring to FIG. 4, operation S120 of calculating the BRDF may include operation S121 of synthesizing a plurality of vision images of the surface of the semiconductor package 1 and operation S122 of obtaining a reflection characteristic of each region of the surface of the semiconductor package 1 from the plurality of vision images. The synthesizing the plurality of vision images is to obtain a first synthesis image. The reflection characteristic of each of the segments may be obtained from the first synthesis image. Therefore, the BRDF on the surface of the semiconductor package 1 may be obtained by using the plurality of vision images.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The plurality of vision images may denote images obtained by each of a plurality of illuminations 120. At least two or more of vision images may be obtained respectively based on irradiation directions of light irradiated from the at least two or more of illuminations 120. The illuminations 120 may be arranged at certain angles with respect to the surface of the semiconductor package 1. In an embodiment, the illuminations 120 may irradiate light onto the semiconductor package 1. Because the latitude θ and longitude Φ of each of the illuminations 120 is different from others, the irradiation angles of light may be different from each other. In an embodiment, light irradiated from each illumination 120 may be reflected from the surface of the semiconductor package 1 and may be collected by the light receiving unit 130 disposed in the housing 110 to form a vision image. The vision image obtained by the light receiving unit 130 may include information about an irradiation direction of light or an arrangement angle of the illumination 120, in addition to an information about light reflected from the surface of the semiconductor package 1.

In operation S122 of obtaining a reflection characteristic of each region (i.e., segments) of the surface of the semiconductor package 1 from the plurality of vision images, the semiconductor package 1 may be a reflector having a characteristic of surface reflection where light reflection intensity obey Lambertian's cosine law, based on a surface angle of the semiconductor package 1. Light reflection intensity based on the surface angle of the semiconductor package 1 may be expressed as the following Equation 1.

$$I = \frac{ρ}{π} kc cos θ = ρ n \cdot s ( \frac{kc}{π} = 1 ) \qquad [ Equation 1 ]$$

Here, I may denote intensity of reflected light on the surface of the semiconductor package 1 obtained from a vision image, ρ may denote a surface reflection coefficient (i.e., reflection characteristic) of the semiconductor package 1, n may denote a normal vector of a sample surface, and s may denote a direction vector of source light irradiated from the illumination 120.

Operation S120 of calculating the BRDF may include operation S123 of separating and calculating a reflection coefficient ρ_{diffuse} of a diffusive light component and a reflection coefficient ρ_{specular} of a specular light component by using the latitude θ and longitude Φ of the illumination 120, in the reflection characteristic ρ described above. The reflection coefficient ρ_{diffuse} of the diffusive light component and the reflection coefficient ρ_{specular} of the specular light component may be calculated from the reflection characteristic ρ of each of the segments with respect to the first set of latitudes and longitudes. For example, The reflection characteristic ρ of the semiconductor package 1 may include the reflection coefficient ρ_{diffuse} of the diffusive light component and the reflection coefficient ρ_{specular} of the specular light component. The reflection characteristic ρ of the semiconductor package 1 may be separated into a reflection coefficient ρ_{diffuse} of the diffusive light component and a reflection coefficient ρ_{specular} of the specular light component. Operation S123 of separating may use a photographic direction information of the camera and the irradiation direction information about source light included in the obtained vision images.

Operation S120 of calculating the BRDF may include operation S124 of obtaining a three-dimensional (3D) shape information from the reflection coefficient ρ_{diffuse} of the diffusive light component, the reflection coefficient ρ_{specular} of the specular light component, and a normal vector of each reflection coefficient, with respect to each region.

The 3D shape information on each of the regions of the surface of the semiconductor package 1 may include the reflection coefficient ρ_{diffuse} of the diffusive light component, the reflection coefficient ρ_{specular} of the specular light component, and the normal vector n. The 3D shape information of each of the plurality of vision images may be a combination of the reflection coefficient ρ_{diffuse} of the diffusive light component, the reflection coefficient ρ_{specular} of the specular light component, and the normal vector n. For example, each of the plurality of vision images may include a multiplication of a reflection coefficient ρ_{specular} of a specular light component of multiplication of a reflection coefficient ρ_{diffuse} of a diffusive light component of each regions of the surface. Each of the plurality of vision images may further include the normal vector n of each regions of the surface.

FIG. 5 is a flowchart of an operation of rendering a vision image of a semiconductor package, according to an embodiment. FIG. 5 may be described in conjunction with FIGS. 2A to 2C.

Operation S130 of rendering may include operation S131 of setting an arbitrary light irradiation direction, with respect to a latitude θ and a longitude Φ where an illumination is not designated. The latitude θ and the longitude Φ, where an illumination is not designated, may denote the illumination non-designation region 122 of FIG. 2C. The rendering of the plurality of vision images may be performed by using the BRDF to obtain a rendered image including an image information obtained by using virtual light. The virtual light is from a plurality of virtual illuminations disposed at second positions corresponding to a second set of latitudes and longitudes. The first set of latitudes and longitudes is different from the second set of latitudes and longitudes. In a virtual condition of the virtual illumination being disposed in the illumination non-designation region 122 in the semispherical housing 110, an arbitrary light irradiation direction of each of the virtual illuminations may be set. The arbitrary light irradiation direction may be a direction from a point on a surface of the semiconductor package 1 to the virtual illumination. The arbitrary light irradiation direction may be a direction which sees a light source at a point of the surface of the semiconductor package 1, and thus, may denote a direction opposite to an illuminating direction of the virtual illumination. In an embodiment of the invention, the number of points, at which virtual illuminations are virtually disposed for the arbitrary light irradiation directions, may be infinite.

Operation S130 of rendering the semiconductor package 1 in the arbitrary light irradiation direction may include operation S132 of obtaining a rendering image, based on the reflection coefficient ρ_{diffuse} of the diffusive light component, the reflection coefficient ρ_{specular} of the specular light component, the normal vector n of each reflection coefficient, and a reverse direction vector of the arbitrary light irradiation direction.

Operation S132 of obtaining the rendering image may render each of 3D shapes of the semiconductor packages 1 in the arbitrary light irradiation direction. The rendering may be performed by using information about 3D shape of the surface of the semiconductor packages 1 which are obtained in operation S124. Accordingly, the rendered images (i.e., rendered images) may be obtained and may be stored in a form of a database, so as to be used to calculate optical attributes of the semiconductor packages 1. For example, a rendered image including an image information may be obtained by using virtual light by using the BRDF with respect to an illumination non-designation region.

In an embodiment, a rendered image of the surface of the semiconductor package 1 based on an arbitrary light irradiation angle (i.e., arbitrary light irradiation direction) may be obtained through rendering based on the reflection coefficient ρ_{diffuse} of the diffusive light component, the reflection coefficient ρ_{specular} of the specular light component, the normal vector n of each reflection coefficient, and the reverse direction vector of the arbitrary light irradiation direction. For example, the rendered image obtained by using the reflection coefficient of the diffusive light component of each of the segments, the reflection coefficient of the specular light component of each of the segments, the normal vector of the reflection coefficients, and a reverse direction vector of the arbitrary light irradiation direction of each of the plurality of virtual illuminations with respect to each of the segments. A rendering image may be obtained as expressed in the following Equation 2.

$$R = {ρ}_{diffuse} {n}_{diffuse} \cdot s + {ρ}_{specular} {n}_{specular} \cdot s \qquad [ Equation 2 ]$$

Here, ρ_{diffuse} may denote a reflection coefficient of a diffusive light component, ρ_{specular} may denote a reflection coefficient of a specular light component, ρ_{diffuse} may denote a normal vector of a diffusive light component in the surface of the semiconductor package 1, n_{specular} may denote a normal vector of a specular light component in the surface of the semiconductor package 1, and s may denote a reverse direction vector of an arbitrary light irradiation direction.

Therefore, an inner product of the reverse direction vector s and the multiplication of the normal vector n_{diffuse} and the reflection coefficient ρ_{diffuse} may be calculated. An inner product of the reverse direction vector s and the multiplication of the normal vector n_{specular} and the reflection coefficient ρ_{specular} may be calculated. A rendered image, as expressed in Equation 2, may be obtained from the sum of two calculated inner products.

In an embodiment, rendering on a vision image of the surface of the semiconductor package 1 based on an arbitrary light irradiation angle may be performed by a cartesian tensor rendering method. The method may simultaneously measure a shape and a reflection characteristic of a measurement target object (e.g., roughness of the package surface). The shape and the reflection characteristic of the measurement target object may be obtained by using a high-order spherical function requiring the abnormal reflection, shadow, or other reflection effect of a surface. The method may measure a reflectance by using the cartesian tensor rendering method and may arbitrarily adjust an incident angle (°) based on the illumination 120 in an entire measurement region of the semiconductor package 1.

In the cartesian tensor rendering method, instead of an arbitrary light irradiation direction (i.e., virtual illumination), at least nine illuminations 120 (i.e., not virtual illumination but actual) are used. The at least nine illuminations 120 may be disposed at predetermined positions in the illumination designation region 121. A surface image (i.e., vision image) corresponding to a latitude θ and a longitude Φ where each of the illuminations 120 may be obtained. As the number of images obtained by the illuminations 120 increases, the accuracy of rendering may increase. A framework capable of expressing a cartesian tensor equal to a multi-lobe may be needed. In the framework, as described above, as the amount of input data increases, the cartesian tensor may be more accurately expressed. A spherical function may be a direction or unit vector function and may thus be expressed as the following Equation 3.

$$v = {( \begin{matrix}{v}_{1} & {v}_{2} & {v}_{3}\end{matrix} )}^{T} \qquad [ Equation 3 ]$$

In this case, a function T raised to the power of a unit vector may be expressed as the following Equation 4 by using the cartesian tensor.

$$T ( v ) = {\sum }_{k + l + m = n} {{T}_{klm} ( {v}_{1} )}^{k} {( {v}_{2} )}^{l} {( {v}_{3} )}^{m} \qquad [ Equation 4 ]$$

Here, T may denote a final image corresponding to a direction vector “v” of light based on the illumination 120, Tₖₗₘ may denote a tensor coefficient, and k, l, and m may be integers instead of negative. In the cartesian tensor, as n increases, a high frequency component may be better expressed. Accordingly, a geometrically higher-order specular reflection lobe may be included therein.

A Lambertian model having a certain reflection in all directions may be associated with an orthogonal tensor. When a direction of a light source is defined as v=(v₁ v₂ v₃)^{T}, the normal line of the surface of the semiconductor package 1 is defined as n=(n₁ n₂ n₃)^{T}, and a surface reflection coefficient of the semiconductor package 1 is defined as ρ as described above, a Lambertian kernel may be expressed as the following Equation 4.

$$\begin{matrix}Max ( ρ , n \cdot v , 0 ) = ρ \cdot max ( {n}_{1} {v}_{1} + {n}_{2} {v}_{2} + {n}_{3} {v}_{3} , 0 ) \\ = max ( {\sum }_{k + l + m = n} {{T}_{klm} ( {v}_{1} )}^{k} {( {v}_{2} )}^{l} {( {v}_{3} )}^{m} , 0 )\end{matrix} \qquad [ Equation 4 ]$$

A first-order cartesian tensor may be expressed as T₁₀₀=ρ·n₁, T₀₁₀=ρ·n₂, T₀₀₁=ρ·n₃. This may be expressed to be equal to the Lambertian kernel. Herein, first to fifth-order cartesian tensors may be used, and a coefficient of each order may use 3, 6, 10, 15, and 21. In even-number orders, cartesian tensors may be symmetric with one another. That is, a cartesian tensor may be (T(v)=T(−v)). In odd-number orders, cartesian tensors may be asymmetric. That is, a cartesian tensor may be (T(v)=−T(−v)). In an embodiment, a cartesian tensor of each image pixel may be calculated based on nine or more images and vector information corresponding to each of the images. The calculated cartesian tensor may be substituted into an image formation equation of a light vector. The image formation equation may denote the BRDF which is calculated in operation S120 of calculating the BRDF described above. The illumination non-designation region 122 may be assumed to be an individual pixel and may be represented through tensor fitting on each pixel.

A two-dimensional (2D) Fourier transform may be performed on a second synthesis image of the rendered image and at least portion of the plurality of vision images to obtain a power spectrum density (PSD) on the surface.

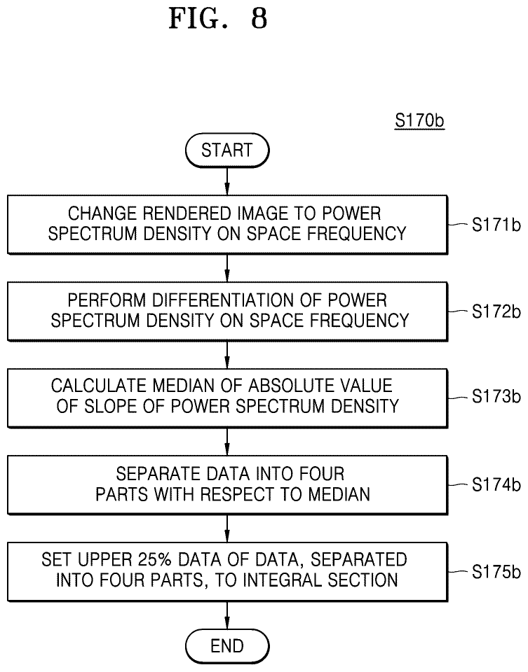

FIG. 6 is a flowchart of an operation of selecting an integral section of a PSD function, according to an embodiment. FIG. 7A is a graph showing a correlation of a PSD with respect to a space frequency q, according to an embodiment. FIG. 7B is a graph showing a correlation of a slope absolute value of a power energy spectrum density with respect to a space frequency, according to an embodiment. FIG. 7C is a graph showing an integral section according to an embodiment. FIG. 8 is a flowchart of an operation of selecting an integral section of a PSD function, according to another embodiment. FIGS. 6 to 8 may be described in conjunction with FIGS. 1 to 5.

Referring to FIG. 6, operation S170a of selecting an integral section may include operation S171a of calculating a PSD with respect to a space frequency q in a rendered image. An operation of calculating the PSD in the rendered image may be represented as in FIG. 7A. The PSD may be changed to a PSD function, wherein the PSD is a function of a space frequency. The abscissa axis may represent a value where a log function is applied to the space frequency q, though only the label q may be used for convenience of description and illustration. A fluctuation region, where a variation of an amplitude is large, of a region of the abscissa axis may be an integral section and may be defined as a range of valid frequency. To define an integral section, the PSD may be changed to a function f(q).

Operation S170a of selecting the integral section may include operation S712a of performing a differentiation of a PSD value on the space frequency q, operation S174a of setting a threshold value, and operation S175a of setting a section. The differentiation of the PSD on the space frequency may be performed by using the PSD function. Referring to FIG. 7B, FIG. 7B is a graph where an absolute value |f′(q)| of a slope of the PSD is represented in the ordinate axis. In an embodiment, when a threshold value is set to 10, PSD points at which the absolute value |f′(q)| of the slope of the PSD is greater than or equal to the threshold value may correspond to PSD points denoted by circles in the graph of FIG. 7B. In operation S175a, a region including all PSD points denoted by the circles may be selected as an integral section. In an embodiment, a range including at least portion of the plurality of points denoted by the circles may be selected as an integral section.

The selected integral section may be as illustrated in FIG. 7C. A value, obtained by performing an integral of the PSD on the space frequency q in the range of valid frequency which is an integral section, may be defined as V. The set threshold value of 10 is only an embodiment and not limited thereto.

Operation S170b of selecting the integral section may include operation S171b and operation S172b. The operations S171b and S171d may respectively correspond to operation S171a and operation S171b.

Operation S170b of selecting the integral section may include operation S173b of calculating a median of the absolute values (which correspond to |f′(q)| in FIG. 7B) of the slopes of the PSD, operation S174b of separating data (i.e., the absolute values) into four groups by quartiles with respect to the median, and operation S175b of setting upper 25% of the data to an integral section. For example, a selected group among the four groups may include upper 25% values among the absolute values, and each of the upper 25% values is greater than values of unselected groups. A range including at least portion of the upper 25% values may be set as the integral section.

When selecting the integral section, at least one of operation S170a and operation S170b may be performed based on the kind of the semiconductor package 1 and a characteristic of the illumination 120.

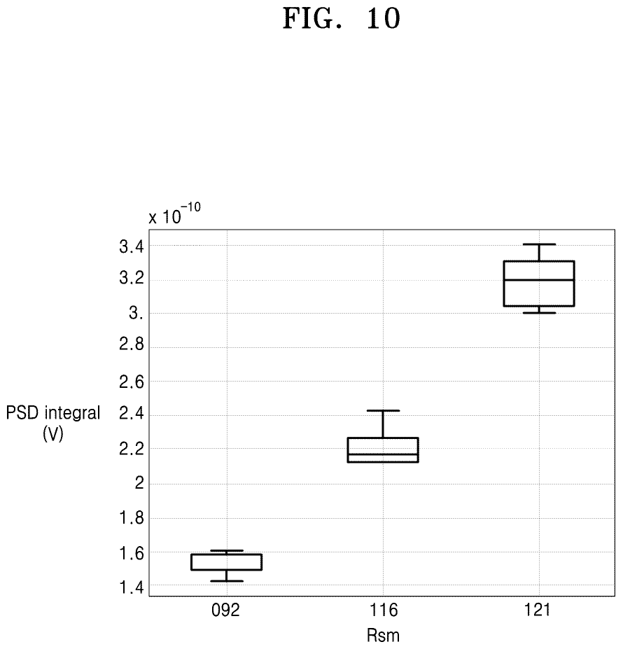

FIG. 9A is a flowchart of an operation of performing an integral on a PSD, according to an embodiment. FIG. 9B is a flowchart of an operation of performing an integral on a PSD, according to another embodiment. FIG. 10 is a graph showing a correlation of a PSD integral value V with respect to an index Rsm, according to another embodiment. FIG. 11A is a graph showing an index Ra according to an embodiment. FIG. 11B is a graph showing an index Rz according to another embodiment. FIG. 11C is a graph showing an index Rsm according to another embodiment. FIGS. 9A to 11C may be described in conjunction with FIGS. 1 to 8.

Referring to FIG. 9A, operation S180a of performing an integral to quantify roughness may include operation S181a of calculating an integral value of a PSD on a space frequency q with respect to the integral section selected in FIG. 6 or 8. When a range of space frequency value of the selected integral section is from a to b, an integral value may be calculated as expressed in the following Equation 5.

$$V = {\int }_{a}^{b} PSD dq \qquad [ Equation 5 ]$$

Here, V may denote the integral value of the PSD.

Operation S180a of performing an integral to quantify roughness may include operation S182a of setting an index value based on the measurement target (e.g., width and height) which is determined in operation S140 of FIG. 1. An index according to an embodiment may denote a quantified roughness value.

In an embodiment, referring to FIG. 11A, a center line average value Ra may be an index. The center line average value Ra may be an index representing a roughness average. The index Ra may be an average of a first value in a reference length. The first value may be the absolute of a length up to a cross-sectional curve of a surface from the center line (i.e., x-axis). The center line average value Ra may be expressed as the following Equation 6.

$$Ra = \frac{{\int }_{a}^{b} \vert f ( x ) \vert dx}{l} \qquad [ Equation 6 ]$$

In an embodiment, referring to FIG. 11B, a ten-point average roughness (or a ten point height) Rz may be an index. The ten-point average roughness Rz may denote the difference between five average heights yₚₙ of the highest crest and five average depths yᵥₙ of the lowest crest with respect to an arbitrary reference line of a roughness cross-sectional curve of the PSD function. The ten-point average roughness Rz may be expressed as the following Equation 7.

$$Rz = ( {\sum }_{i = 1}^{5} {y}_{pi} - {\sum }_{i = 1}^{5} {y}_{{v}_{i}} ) / 5 \qquad [ Equation 7 ]$$

The center line average value Ra and the ten-point average roughness Rz may each be an index for a height of roughness. When the measurement target determined in operation S140 of FIG. 1 is a height, the center line average value Ra and the ten-point average roughness Rz may each be an index of an image which is selected in operation S150b.

In an embodiment, referring to FIG. 11C, a width average Rsm of a profile factor may be an index. The width average Rsm of the profile factor may denote an average of a profile factor of a roughness cross-sectional surface in an evaluation length. The width average Rsm of the profile factor may be expressed as the following Equation 8.

$$Rsm = \frac{1}{m} {\sum }_{i = 1}^{m} {x}_{{s}_{i}} \qquad [ Equation 8 ]$$

The width average of the profile factor may be an index of a width of roughness. When the measurement target determined in operation S140 of FIG. 1 is a width, the width average of the profile factor may be an index of an image which is selected in operation S150a.

Operation S180a of performing an integral to quantify roughness may include operation S183a of calculating an integral value distribution of an index in a case which selects an index value based on the measurement target.

Operation S180b of performing an integral to quantify roughness may include operation S181b and operation S182b, which may respectively correspond to operation S181a and operation S182a. Operation S180b of performing an integral to quantify roughness may include operation S183a of fitting a correlation function of an integral value of an index.

Operation S183a, as illustrated in FIG. 10, may include preparation of a box-plot graph of an integral value of the PSD for each index (i.e., each measured sample). The x axis of FIG. 10 represents an index of Rsm and denotes that Rsm values are 92 μm, 116 μm, and 121 μm. To describe trends of an Rsm index and an integral value V, it may be seen that an integral value is largely calculated as a width of roughness increases, namely, in a case of 121 μm rather than a case of 92 μm. Also, the integral value ranges do not overlap with each other with respect to the three Rsm values. Accordingly, high-resolution and high-accuracy of the measuring and inspection may be accomplished.

Operation S183b may obtain a correlation function corresponding to a relationship between an index and the PSD on which box plotting has been performed. For example, the correlation function may correspond to a relationship between the index and the PSD. The correlation function may be a first-order function, a second-order function, a third-order function, or an exponential function.

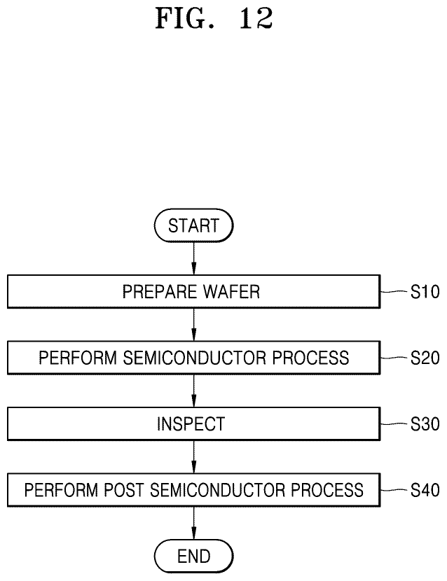

FIG. 12 is a flowchart of a method of manufacturing a semiconductor device by using a semiconductor package inspection method, according to an embodiment. FIG. 12 may be described in conjunction with FIGS. 1 to 10.

Referring to FIG. 12, first, operation S10 of preparing a wafer W may be performed. The wafer W may include, for example, a silicon wafer on which one or more front-end semiconductor manufacturing processes (i.e., semiconductor processes) have been performed (or any front-end semiconductor manufacturing process is not performed).

Subsequently, operation S20 of performing a front-end semiconductor manufacturing process on the wafer W may be performed. For example, an oxidation process, a photo process, a deposition process, an etching process, an ion process, and/or a cleaning process may be performed on the wafer W.

Subsequently, inspection S30 may be performed. Inspection S30 may perform an operation corresponding to the semiconductor inspection method S100 of FIG. 1.

Subsequently, a back-end semiconductor manufacturing process (i.e., post semiconductor process) may be performed on the wafer W in operation 540. The back-end semiconductor manufacturing process on the wafer W may include various processes. For example, the back-end semiconductor manufacturing process may include a singularization process of individualizing the wafer W into semiconductor chips and a test process of testing the semiconductor chips. Further, a packaging process may be performed. Fabrication of a semiconductor device may be finished through the back-end semiconductor manufacturing process on the wafer W. After operation 540, additional inspection may be performed on a package manufactured by the packaging process.

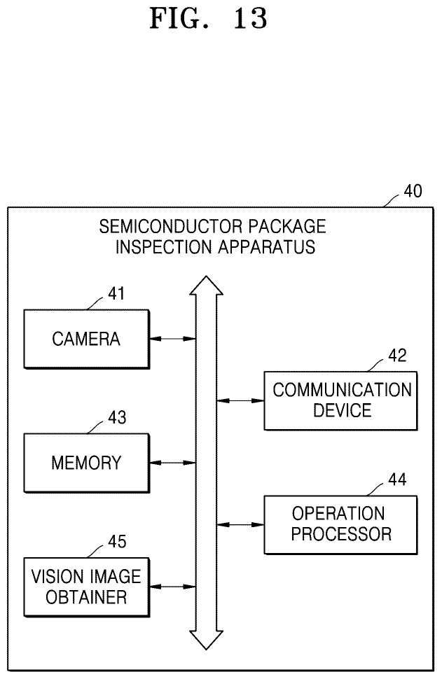

FIG. 13 is a schematic block diagram of a semiconductor package inspection apparatus 40 according to an embodiment. FIG. 13 may be described in conjunction with FIGS. 1 to 12.

Referring to FIG. 13, the semiconductor package inspection apparatus 40 may include a camera 41, a communication device 42, a memory 43, an operation processor 44, and a vision image obtainer 45. However, elements included in the semiconductor package inspection apparatus 40 are not limited to the elements described above, and the semiconductor package inspection apparatus 40 may include other elements for inspecting the semiconductor package 1. The camera 41 of FIG. 13 may correspond to the light receiving unit 130 of FIGS. 1 to 12. Operation S110 may be performed by the camera 41.

According to an embodiment, the camera 41 may be configured to detect scattered light reflected from the semiconductor package 1. The communication device 42 may provide network communication to the semiconductor package inspection apparatus 40. The network may be a wired network and/or a wireless network such as radio, cellular, satellite, and broadcasting. In an embodiment, the semiconductor package inspection apparatus 40 may include an electronic device, where an image processing program is installed, such as a computer, a smartphone, a personal computer, or a server.

According to an embodiment, a vision image detected by the camera 41 may be recognized as a 3D figure. The operation processor 44 may digitize the recognized figure to generate an inspection profile. Also, the operation processor 44 may digitize an inspection profile, a reference profile stored in the memory 43, and/or a reference profile generated by digitizing a vision image captured by the camera 41 to detect roughness of the semiconductor package 1. The operation processor 44 may perform operations S120, S130, S150a, S150b, S160, S170, and S180.

According to an embodiment, the memory 43 may include, for example, flash memory, a hard disk drive (HDD), a solid state drive (SSD), dynamic random access memory (DRAM), and static random access memory (SRAM). For example, the operation processor 44 may include a central processing unit (CPU), a graphics processing unit (GPU), a vector processor, a quantum operation processor, and an embedded operation processor. For example, the vision image obtainer 45 may include an image scanner. The vision image obtainer 45 may perform operation S110 along with the camera 41. In the drawing, the vision image obtainer 45 is illustrated as a device which is lastly used in processing quantification of roughness of the surface of the semiconductor package 1, based on a vision image. However, in processing quantification of roughness of the surface of the semiconductor package 1, the order thereof is not limited to the illustration.

Hereinabove, embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

What is claimed is:

1. An inspection method comprising:
providing a semiconductor package including a surface, the surface including a plurality of segments;
obtaining a plurality of vision images by using light from a plurality of illuminations, wherein the plurality of illuminations are disposed at first positions corresponding to a first set of latitudes and longitudes;
obtaining a bidirectional reflectance distribution function (BRDF) on the surface by using the plurality of vision images;
rendering the plurality of vision images by using the BRDF to obtain a rendered image including an image information obtained by using virtual light, wherein the virtual light is from a plurality of virtual illuminations disposed at second positions corresponding to a second set of latitudes and longitudes, and the first set of latitudes and longitudes is different from the second set of latitudes and longitudes,
performing a two-dimensional (2D) Fourier transform on a first synthesis image of the rendered image and at least portion of the plurality of vision images to obtain a power spectrum density (PSD) on the surface;
selecting an integral section of the PSD; and
performing an integral on the PSD in the integral section to quantify roughness of the surface.

2. The inspection method of claim 1, wherein the obtaining of the plurality of vision images comprises:
preparing a light receiver configured to a detect a light information from the surface;
inputting an information of wavelength and intensity to the plurality of illuminations, wherein the plurality of illuminations is disposed repeatedly by a latitudinal interval in each longitudes, and the plurality of illuminations is disposed repeatedly by a longitudinal interval in each latitudes;
inputting power to the plurality of illuminations; and
obtaining the plurality of vision images by using the light receiver.

3. The inspection method of claim 1, wherein the obtaining of the BRDF comprises:
synthesizing the plurality of vision images to obtain a second synthesis image;
obtaining a reflection characteristic of each of the segments from the second synthesis image;
calculating a reflection coefficient of a diffusive light component and a reflection coefficient of a specular light component from the reflection characteristic of each of the segments with respect to first set of latitudes and longitudes; and
obtaining a three-dimensional (3D) shape information by using the reflection coefficient of the diffusive light component, the reflection coefficient of the specular light component and a normal vector of the reflection coefficients, with respect to each of the segments.

4. The inspection method of claim 3, wherein the rendering of the plurality of vision images comprises:
setting an arbitrary light irradiation direction of each of the plurality of virtual illuminations; and
obtaining a rendered image by using the reflection coefficient of the diffusive light component of each of the segments, the reflection coefficient of the specular light component of each of the segments, the normal vector of the reflection coefficients, and a reverse direction vector of the arbitrary light irradiation direction of each of the plurality of virtual illuminations with respect to each of the segments.

5. The inspection method of claim 1, wherein the selecting of the integral section of the PSD comprises:
changing the PSD to a PSD function, wherein the PSD is a function of a space frequency;
performing a differentiation of the PSD on the space frequency by using the PSD function;
setting a threshold value;
selecting a plurality of PSD points in a graph of the PSD function, wherein absolute values of slopes at each of the plurality of PSD points is greater than or equal to the threshold value; and
setting a range including at least portion of the plurality of PSD points to the integral section.

6. The inspection method of claim 1, wherein the selecting of the integral section of the PSD comprises:
changing the PSD to a PSD function, wherein the PSD is a function of a space frequency;
performing a differentiation of the PSD on the space frequency by using the PSD function;
calculating a median of absolute values of slopes of the PSD;
separating the absolute values into four groups by quartiles with respect to the median;
selecting a selected group among the four groups, wherein the selected group includes upper 25% values among the absolute values, and each of the upper 25% values is greater than values of unselected groups; and
setting a range including at least portion of the upper 25% values as the integral section.

7. The inspection method of claim 1, further comprising:
determining a measurement target of the roughness; and
selecting the at least portion of the plurality of vision images based on the latitude of each of the plurality of illuminations and the measurement target.

8. The inspection method of claim 7, wherein:
when the measurement target is a width, the at least portion of the plurality of vision images is obtained by using light from high-angle illuminations disposed at a first latitudes, and each of the first latitudes has a value between about −15 degrees and about 15 degrees.

9. The inspection method of claim 7, wherein;
when the measurement target is a height, the at least portion of the plurality of vision images is obtained by using light from low-angle illuminations disposed at a second latitudes, and
each of the second latitudes has a value between about −90 degrees and −75 degrees or between about 75 degrees to about 90 degrees.

10. The semiconductor device inspection method of claim 7, wherein the performing of the integral on the PSD comprises:
calculating an integral value of the PSD on a space frequency in the integral section;
setting an index value based on the measurement target; and
calculating a distribution of the integral value of the index.

11. An inspection method comprising:
providing an inspection apparatus comprising;
a semispherical housing;
a light receiver disposed at an uppermost vertex of the semispherical housing, wherein the light receiver is single one light receiver; and
a plurality of illuminations disposed on the semispherical housing, wherein:
the plurality of illuminations is spaced apart from each other and disposed at first positions corresponding to a first set of latitudes and longitudes, and
the plurality of illuminations is disposed repeatedly by a latitudinal interval in each longitudes, and disposed repeatedly by a longitudinal interval in each latitudes,
providing a semiconductor package including a surface;
inputting power to one or more of the plurality of illuminations to irradiate light onto the surface of the semiconductor package;
obtaining a plurality of vision images by detecting reflected light from the surface of the semiconductor package by using the light receiver;
obtaining a BRDF on the surface of the semiconductor package by using the plurality of vision images;
rendering the plurality of vision images by using the BRDF to obtain a rendered image including an image information obtained by using virtual light, wherein:
the virtual light is from a plurality of virtual illuminations disposed at second positions corresponding to a second set of latitudes and longitudes, and
the first set of latitudes and longitudes is different from the second set of latitudes and longitudes,
determining a measurement target of roughness of the surface;
selecting at least portion of the plurality of vision images based on the latitude of each of the plurality of illuminations and the measurement target;
obtaining a synthesis image of the rendered image and the at least portion of the plurality of vision images;
performing a 2D Fourier transform on the synthesis image to calculate a PSD;
selecting an integral section of the PSD; and
performing an integral on the PSD in the integral section to quantify the roughness.

12. The inspection method of claim 11, wherein, the uppermost vertex of the semispherical housing is disposed at a latitude and a longitude of about 0 degree.

13. The inspection method of claim 11, wherein:
each of the plurality of illuminations is configured so that a wavelength and intensity of light emitted therefrom is individually adjusted by a controller, and
light from each of the plurality of illuminations is a visible light.

14. The inspection method of claim 11, wherein, the latitudinal interval is about 15 degrees in each longitude, and the plurality of the illuminations are located between latitude of about −75 degrees to about −15 degrees or about 75 degrees to about 15 degrees in each longitude.

15. The inspection method of claim 11, wherein, the longitudinal interval is about 45 degrees, and the plurality of illuminations in each latitudes are located between longitude of about 0 degree to about 315 degrees in each latitudes.

16. The inspection method of claim 11, wherein the selecting of the integral section of the PSD comprises:
changing the PSD to a PSD function, wherein the PSD is a function of a space frequency;
performing a differentiation of the PSD on the space frequency by using the PSD function;
setting a threshold value;
selecting a plurality of PSD points in a graph of the PSD function, wherein absolute values of slopes at each of the plurality of PSD points is greater than or equal to the threshold value; and
setting a range including at least portion of the plurality of PSD points to the integral section.

17. The inspection method of claim 11, wherein:
when the measurement target is a width, the at least portion of the plurality of vision images is obtained by using light from high-angle illuminations disposed at a first latitude,
when the measurement target of the roughness is a height, the at least portion of the plurality of vision images is obtained by using light from low-angle illuminations disposed at a second latitudes,
each of the first latitudes has a magnitude of the latitude between about −15 degrees and about 15 degrees, and
each of the first latitudes has a magnitude of the latitude between about −90 degrees and −75 degrees or between about 75 degrees to about 90 degrees.

18. The inspection method of claim 17, wherein the performing of the integral on the PSD comprises:
calculating an integral value of the PSD on a space frequency in the integral section;
setting an index value based on the measurement target; and
obtain a correlation function corresponding to a relationship between the index and the PSD, wherein the correlation function is a first-order function, a second-order function, a third-order function, or an exponential function.

19. A semiconductor manufacturing method comprising:
preparing a wafer;
performing a semiconductor manufacturing process on the wafer to obtain a semiconductor package; and
inspecting the semiconductor package,
wherein the inspecting of the semiconductor package comprises:
obtaining a plurality of vision images of a surface of the semiconductor package by using light from a plurality of illuminations with respect to an illumination designation region;
obtaining a BRDF on the surface of the semiconductor package by using the plurality of vision images;
obtain a rendered image including an image information obtained by using virtual light by using the BRDF with respect to an illumination non-designation region;
determining a measurement target of roughness of the surface of the semiconductor package;
selecting at least portion of the plurality of vision images based on a position of each of the plurality of illuminations and the measurement target;
performing a 2D Fourier transform on a first synthesis image of the rendered image and the at least portion of the plurality of vision images to obtain a power spectrum density (PSD) on the surface;
selecting an integral section of the PSD; and
performing an integral on the PSD in the integral section to quantify the roughness.

20. The semiconductor manufacturing method of claim 19, wherein the selecting of the integral section of the PSD comprises:
changing the PSD to a PSD function, wherein the PSD is a function of a space frequency;
performing a differentiation of the PSD on the space frequency by using the PSD function;
calculating a median of absolute values of slopes of the PSD;
separating the absolute values into four groups by quartiles with respect to the median;
selecting a selected group among the four groups, wherein the selected group includes upper 25% values among the absolute values, and each of the upper 25% values is greater than values of unselected groups; and
setting a range including at least portion of the upper 25% values as the integral section.
